(19) United States
(12) Patent Application Publication
(10) Pub. No.: US 2026/0057926 A1
(43) Pub. Date: Feb. 26, 2026

(54) FLEXIBLE REFRESH PERIOD CONTROL FOR DYNAMIC RANDOM-ACCESS MEMORY (DRAM) DIES ON A SYSTEM-ON-CHIP (SOC) BASE DIE BASED ON MONITORED TEMPERATURE SENSORS OF THE DRAM DIES

(71) Applicant: QUALCOMM Incorporated, San Diego, CA (US)

(72) Inventors: Woo Tag KANG, San Diego, CA (US); Mustafa BADAROGLU, San Diego, CA (US); Jihong CHOI, San Diego, CA (US); Zhongze WANG, San Diego, CA (US); Giridhar NALLAPATI, San Diego, CA (US); Periannan CHIDAMBARAM, San Diego, CA (US)

(21) Appl. No.: 19/203,047

(22) Filed: May 8, 2025

Related U.S. Application Data
(60) Provisional application No. 63/687,229, filed on Aug. 26, 2024.

(51) Int. Cl. G11C 11/406

(52) U.S. Cl. CPC G11C 11/40626; G11C 11/40615; G11C 11/40622

(57) ABSTRACT

A method for flexible memory refresh period control is described. The method includes identifying one or more temperature sensors placed in selected regions of one or more memory dies supported by a system-on-chip (SoC) base die during formation of a memory die stack. The method also includes monitoring temperature sensor values of the one or more temperature sensors during operation of the memory die stack. The method further includes adjusting a memory refresh period control of a region of a memory die from the one or more memory dies when a temperature sensor value of a temperature sensor corresponding to the region is greater than the temperature sensor values based on the monitoring.

### CROSS-REFERENCE TO RELATED APPLICATION

The present application claims the benefit of U.S. Provisional PATENT APPLICATION No. 63/687,229, filed Aug. 26, 2024, and titled “FLEXIBLE REFRESH PERIOD CONTROL METHOD ON DYNAMIC RANDOM-ACCESS MEMORY (DRAM) DIE BASED ON A THERMAL HOT SPOT LOCATION OF A SYSTEM-ON-CHIP (SOC) BASE DIE ON THREE-DIMENSIONAL (3D) DRAM,” the disclosure of which is expressly incorporated by reference herein in its entirety.

### BACKGROUND

### Field

Aspects of the present disclosure relate to semiconductor memory devices and, more particularly, to a flexible refresh period control for dynamic random-access memory (DRAM) dies on a system-on-chip (SoC) base die based on monitored temperature sensors of the DRAM dies.

### Background

Memory is a vital component for computing devices, wireless communications devices, and other like computing devices. For example, a cell phone may integrate memory as part of an application processor, such as a system-on-chip (SoC) including a central processing unit (CPU) and a graphics processing unit (GPU). Successful operation of some wireless applications depends on the availability of high-capacity and low-latency memory solutions for scalability of CPU/GPU workload. A semiconductor memory device solution for providing a high-capacity, low-latency, and high-bandwidth memory is an existing goal for system designers.

Semiconductor memory devices include, for example, a dynamic random-access memory (DRAM). A DRAM cell includes one transistor and one capacitor, thereby providing a high degree of integration. DRAM-on-logic, however, is hindered by temperature envelope limitations of DRAM on localized thermal regions (e.g., hotspots) of the CPU/GPU of a system-on-chip (SoC). In practice, memory intensive applications (e.g., artificial intelligence (AI)) consume extensive amounts of DRAM, which involve cell retention time control due to refresh specifications of DRAM devices. Unfortunately, thermal generation from an SoC logic device complicates cell retention time control. One potential future solution involves directly stacking a three-dimensional (3D) DRAM above an SoC base die. This potential future solution of 3D DRAM stacking above the SoC base die, however, results in issues due to localized thermal regions (e.g., hotspots) of the SoC logic device, which negatively impact the DRAM retention time, potentially resulting in a DRAM cell failure. Therefore, a solution for overcoming the DRAM cell retention time control caused by localized thermal regions of SoC logic devices, is desired.

### SUMMARY

A method for flexible memory refresh period control is described. The method includes identifying one or more temperature sensors placed in selected regions of one or more memory dies supported by a system-on-chip (SoC) base die during formation of a memory die stack. The method also includes monitoring temperature sensor values of the one or more temperature sensors during operation of the memory die stack. The method further includes adjusting a memory refresh period control of a region of a memory die from the one or more memory dies when a temperature sensor value of a temperature sensor corresponding to the region is greater than the temperature sensor values based on the monitoring.

An apparatus is described as having a base system-on-chip (SoC) logic die. The apparatus includes a three-dimensional (3D) memory die stack on the base SoC logic die. 3D memory die stack includes memory dies. Each of the memory dies having a temperature sensors and a temperature sensor selection circuit. The locations of the temperature sensors correlate with locations of localized thermal regions of the base SoC logic die.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an example implementation of a host system-on-chip (SoC), including a flexible refresh period control for dynamic random-access memory (DRAM) dies on an SoC base die based on monitored temperature sensors of the DRAM dies, in accordance with certain aspects of the present disclosure.

FIG. 2 shows a cross-sectional view of a stacked integrated circuit (IC) package of the host system-on-chip (SoC) of FIG. 1.

FIG. 3 shows a cross-sectional view illustrating the stacked integrated circuit (IC) package of FIG. 2, incorporated into a wireless device, according to one aspect of the present disclosure.

FIG. 4 is a block diagram illustrating a high-bandwidth three-dimensional (3D) stacked memory package configured for a flexible, refresh period control method based on monitoring temperature sensor values of one or more memory dies, according to various aspects of the present disclosure.

FIG. 5 is a block diagram illustrating a top view of the three-dimensional (3D) dynamic random-access memory (DRAM) stack of FIG. 4, having bank-based temperature sensors and a temperature sensor selection circuit, according to further aspects of the present disclosure.

FIG. 6 is a process flow diagram illustrating a method for flexible memory refresh period control, according to various aspects of the present disclosure.

FIG. 7 is a block diagram showing an exemplary wireless communications system, in which an aspect of the present disclosure may be advantageously employed.

FIG. 8 is a block diagram illustrating a design workstation used for circuit, layout, and logic design of a semiconductor component such as the three-dimensional (3D) stacked chip disclosed herein.

### DETAILED DESCRIPTION

The detailed description set forth below, in connection with the appended drawings, is intended as a description of various configurations and is not intended to represent the only configurations in which the concepts described may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form to avoid obscuring such concepts.

As described, the use of the term “and/or” is intended to represent an “inclusive OR,” and the use of the term “or” is intended to represent an “exclusive OR.” As described, the term “exemplary” used throughout this description means “serving as an example, instance, or illustration,” and should not necessarily be construed as preferred or advantageous over other exemplary configurations. As described, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described, the term “proximate” used throughout this description means “adjacent, very near, next to, or close to.” As described, the term “on” used throughout this description means “directly on” in some configurations, and “indirectly on” in other configurations.

Memory is a vital component for wireless communications devices. For example, a cell phone may integrate memory as part of an application processor, such as a system-on-chip (SoC) including one or more processors, e.g., a central processing unit (CPU), a graphics processing unit (GPU), and a neural processing unit (NPU). Successful operation of some wireless applications depends on the availability of a high-capacity and low-latency memory solution for scalability of processor workload. A semiconductor memory device solution for providing a high-capacity, low-latency, and high-bandwidth memory is an existing goal for system designers.

Semiconductor memory devices include, for example, dynamic random-access memory (DRAM). A DRAM cell includes one transistor and one capacitor, thereby providing a high degree of integration. DRAM-on-logic, however, is hindered by temperature envelope limitations of DRAM proximate localized thermal regions (e.g., hotspots) on the processors (e.g., CPU, GPU, NPU) of a system-on-chip (SoC). Integrating DRAM on hot compute logic including the processors (e.g., CPU, GPU, NPU) is problematic because this hot compute logic prevents, or hinders, cooling of the DRAM junction temperatures. These limitations have led to industry implementation of DRAM in a side-by-side configuration with the processors (e.g., CPU, GPU, NPU) of the hot compute logic.

In practice, memory intensive applications (e.g., artificial intelligence (AI)) specify extensive amounts of DRAM, which involve cell retention time control due to memory refresh specifications of DRAM devices. Unfortunately, thermal generation from an SoC base die results in localized thermal regions (e.g., hotspots) that complicate cell retention time control. One potential future solution involves directly stacking a three-dimensional (3D) DRAM above an SoC die. These potential future solutions of 3D DRAM stacking above the SoC base die, however, incur excessive heat from a localized thermal region (e.g., hotspot) of the SoC die, which negatively impacts the DRAM retention time, potentially resulting in a DRAM cell failure. Therefore, a solution for overcoming the DRAM cell retention time control issues caused by localized thermal regions of SoC logic devices, is desired.

Various aspects of the present disclosure provide flexible refresh period control for dynamic random-access memory (DRAM) dies on a system-on-chip (SoC) base die based on monitored temperature sensors of the DRAM dies. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. As further described, the term “laminate” may refer to a multilayer sheet to enable packaging of an IC device. As described, the term “chiplet” may refer to an integrated circuit block, a functional circuit block, or other like circuit block specifically designed to work with other similar chiplets to form a larger, more complex chiplet architecture. The terms “substrate,” “wafer,” and “laminate” may be used interchangeably. Similarly, the terms “chip,” “chiplet,” and “die” may be used interchangeably.

Various aspects of the present disclosure overcome the noted thermal issues by providing a flexible refresh period control for DRAM dies in a memory die stack based on monitored, localized thermal regions of the DRAM dies (e.g., hotspots). In some implementations, improved DRAM cell refresh control ensures a predetermined memory cell retention regardless of different base die localized thermal regions (e.g., hotspots) by different SoC base die designs. In this implementation, additional temperature sensor locations are provided in a 3D DRAM die stack to accommodate the DRAM retention control based on the different localized thermal regions of the SoC base die having a temperature outside a normal, operating temperature range.

For example, different DRAM cell refresh period controls are performed according to different temperature sensor locations on the DRAM die. In this example, additional temperature sensors are added based on expected, localized thermal regions and/or assumed localized thermal regions of an SoC base die. In other words, the locations of the temperature sensors correlate with locations of localized thermal regions of the SoC base die. In some implementations, a temperature sensor is added to a selected location of each DRAM die during formation of the 3D DRAM die stack. For example, a temperature sensor may be added per bank, and/or several temperature sensors may be added per unit refresh macro of the DRAM die. These temperature sensor placements in selected regions enable implementation of different refresh period controls per bank or refresh control macro using a refresh control block.

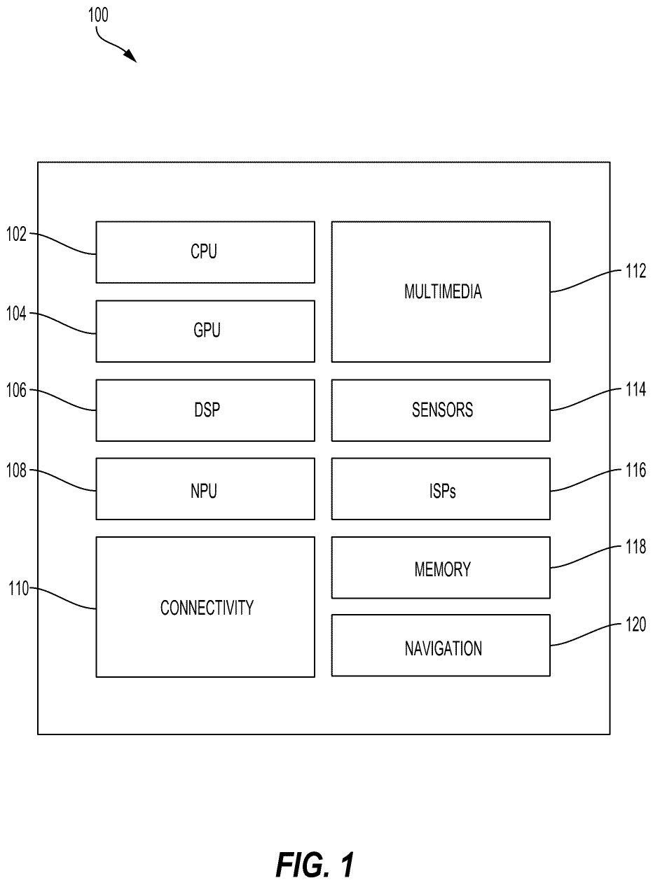

FIG. 1 illustrates an example implementation of a host system-on-chip (SoC) 100, which includes a flexible refresh period control for dynamic random-access memory (DRAM) dies on an SoC base die based on monitored temperature sensors of the DRAM dies, in accordance with certain aspects of the present disclosure. The host SoC 100 includes processing blocks tailored to specific functions, such as a connectivity block 110. The connectivity block 110 may include sixth generation (6G) connectivity, fifth generation (5G) new radio (NR) connectivity, fourth generation long term evolution (4G LTE) connectivity, Wi-Fi connectivity, USB connectivity, Bluetooth® connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU) 108. The host SoC 100 may also include a sensor processor 114, image signal processors (ISPs) 116, a navigation module 120, which may include a global positioning system (GPS), and a memory 118. The multi-core CPU 102, the GPU 104, the DSP 106, the NPU 108, and the multi-media engine 112 support various functions such as video, audio, graphics, gaming, artificial networks, and the like. Each processor core of the multi-core CPU 102 may be a reduced instruction set computing (RISC) machine, RISC-V, an advanced RISC machine (ARM), a microprocessor, or any reduced instruction set computing (RISC) architecture. The NPU 108 may be based on an ARM instruction set.

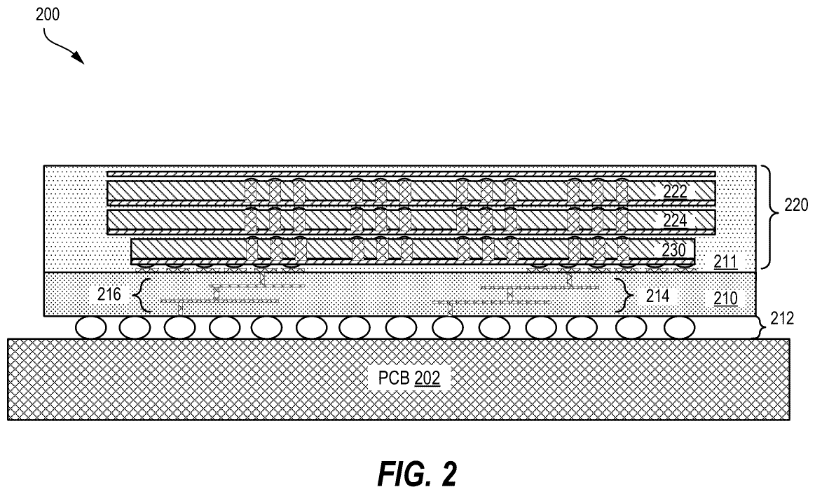

FIG. 2 shows a cross-sectional view of a stacked integrated circuit (IC) package 200 of the host system-on-chip (SoC) 100 of FIG. 1. Representatively, the stacked IC package 200 includes a printed circuit board (PCB) 202 connected to a package substrate 210 with interconnects 212. In this configuration, the package substrate 210 includes conductive layers 214 and 216. Above the package substrate 210 is a 3D chip stack 220, including stacked dies 222, 224, and 230, encapsulated by mold compound 211. In one aspect of the present disclosure, the die 230 is the host SoC 100 of FIG. 1.

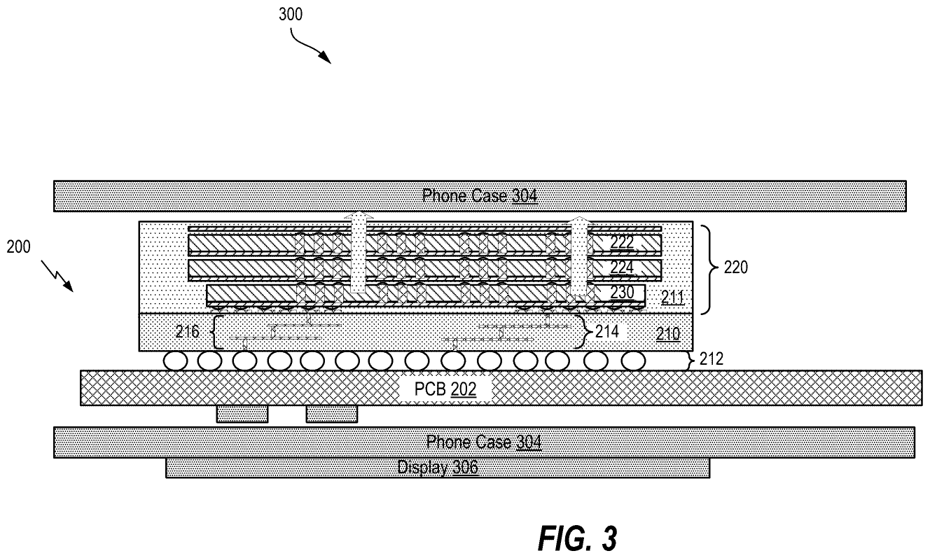

FIG. 3 shows a cross-sectional view illustrating the stacked integrated circuit (IC) package 200 of FIG. 2, incorporated into a wireless device 300, according to one aspect of the present disclosure. As described, the wireless device 300 may include, but is not limited to, a smartphone, tablet, handheld device, or other limited form factor device configured for 5G NR/6G communications. Representatively, the stacked IC package 200 is within a phone case 304, including a display 306.

In practice, memory intensive applications (e.g., artificial intelligence (AI)) specify extensive amounts of dynamic random-access memory (DRAM), which involve cell retention time control due to memory refresh specifications of DRAM devices. Unfortunately, thermal generation from a system-on-chip (SoC) base die results in localized thermal regions (e.g., hotspots) that complicate cell retention time control. One potential future solution involves directly stacking a three-dimensional (3D) DRAM above an SoC base die. These potential future solutions of 3D DRAM stacking above the SoC base die, however, incur excessive heat from a localized thermal region of the SoC base die, which negatively impacts the DRAM retention time, potentially resulting in a DRAM cell failure.

Conventional DRAM includes a limited number of temperature sensors that are not necessarily aligned with an SoC base die's localized thermal regions. Unaligned temperature sensors are a critical issue for performing DRAM refresh control, especially when a 3D DRAM stack is supported by an SoC base die. In this 3D DRAM stack configuration, a direct thermal impact from the SoC base die detrimentally affects a cell retention time of the DRAM die in the 3D DRAM stack. In short, the direct thermal impact from the SoC base die negatively impacts the DRAM retention time, potentially resulting in a DRAM cell failure. Therefore, accurate DRAM temperature sensor monitoring is desired to ensure DRAM cell retention regardless of different base die localized thermal regions from different SoC base die designs.

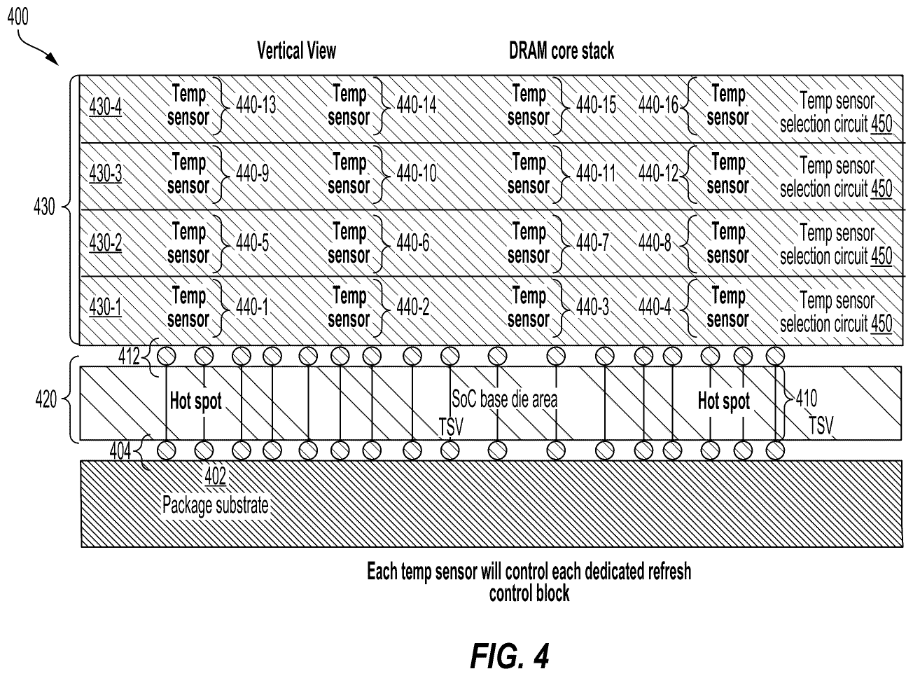

In various aspects of the present disclosure, a flexible refresh period control method is implemented on DRAM die based on localized thermal regions of an SoC base die supporting a 3D DRAM die stack in the stacked IC package 200. The flexible refresh period control method supports 3D chip stacking and ensures a predetermined DRAM cell retention regardless of different base die localized thermal regions from different SoC base die designs, for example, as shown in FIG. 4.

FIG. 4 is a block diagram illustrating a high-bandwidth three-dimensional (3D) stacked memory package configured for a flexible, refresh period control method based on monitoring temperature sensor values of one or more memory dies, according to various aspects of the present disclosure. The high-bandwidth 3D stacked memory package 400 may be referred to as a system-in-package (SIP) in some implementations. As shown in FIG. 4, the high-bandwidth 3D stacked memory package 400 includes a package substrate 402 having first micro-bumps 404 for supporting a system-on-chip (SoC) base die 420. In this configuration, the SoC base die 420 includes second micro-bumps 412 (or hybrid bonding pads) for supporting a 3D dynamic random-access memory (DRAM) stack 430 of DRAM dies (e.g., 430-1, 430-2, 430-3, 430-4). The number of DRAM dies in the 3D DRAM stack 430 can vary in different implementations. Additionally, the SoC base die 420 includes through silicon vias (TSVs) 410, which are shown extending through the SoC base die 420, between the first micro-bumps 404 and the second micro-bumps 412 (or hybrid bonding pads).

In some implementations, an improved DRAM cell refresh control ensures a predetermined DRAM cell retention of the 3D DRAM stack 430 regardless of different localized thermal regions of the SoC base die 420. In this example, additional ones of temperature sensors 440 (440-1, . . . 440-16) are provided in the 3D DRAM stack 430 to accommodate the DRAM retention control based on the different localized thermal regions of the SoC base die 420. For example, different DRAM cell refresh period controls are performed according to the various locations of the temperature sensors 440 on the DRAM dies (e.g., 430-1, 430-2, 430-3, 430-4) of the 3D DRAM stack 430. In this example, the temperature sensors 440 are added to the DRAM dies based on expected localized thermal regions and/or assumed localized thermal regions of the SoC base die 420 supporting the 3D DRAM stack 430. The number of temperature sensors 440 varies in different implementations.

As shown in FIG. 4, DRAM temperature sensor selection circuits 450 (or fuse options) are added to the DRAM dies (e.g., 430-1, 430-2, 430-3, 430-4) of the 3D DRAM stack 430 for programming the temperature sensor location selection. The DRAM temperature sensor selection circuits 450 are configurable to perform refresh control for any bank combination among banks available on the DRAM dies (e.g., 430-1, 430-2, 430-3, 430-4) of the DRAM stack 430. In the multiple 3D DRAM stacking of FIG. 4, different temperature sensor selections on each of the DRAM dies improve the DRAM refresh control among the 3D DRAM stack 430. The different sensor selections can resolve the DRAM refresh control issue caused by the DRAM temperature variations among the DRAM dies of the 3D DRAM stack 430 utilizing a refresh control block.

Alternatively, higher temperature sensor readings from the temperature sensors 440 are selected for performing the DRAM refresh control, which simplifies the DRAM refresh operation while overcoming the noted DRAM refresh issue caused by incorrect or inaccurate temperature reading. Additionally, one or more temperature sensors among these multiple temperature sensors can be selected according to the localized thermal regions of the SoC base die 420. Selecting temperature sensors provides refresh period control on a partial portion of the 3D DRAM stack 430. In some implementations, the DRAM temperature sensor selection circuits 450 enable a programmable temperature sensor location, which ensures the DRAM refresh maintains desired cell retention times according to the SoC base die's different localized thermal regions. Therefore, the DRAM temperature sensor selection circuits 450 support a more robust and reliable DRAM refresh control feature, even if the localized thermal region of the SoC base die 420 is unknown during or after DRAM design completion.

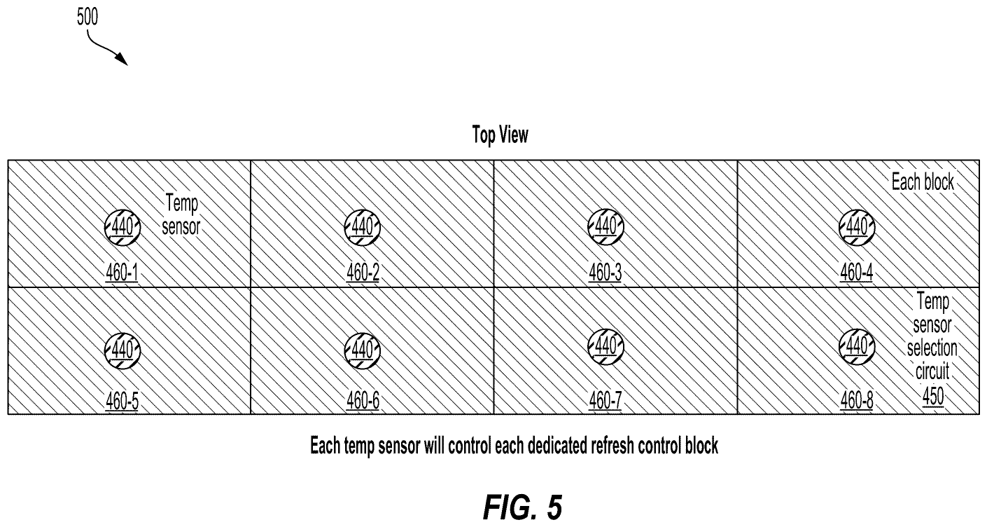

FIG. 5 is a block diagram illustrating a top view 500 of the three-dimensional (3D) dynamic random-access memory (DRAM) stack 430 of FIG. 4, having bank-based temperature sensors and a temperature sensor selection circuit, according to further aspects of the present disclosure. In some implementations, the temperature sensors 440 are added to a predetermined number of locations of the DRAM dies of the 3D DRAM stack 430 during formation of the 3D DRAM stack 430. For example, temperature sensors 440 may be added per bank 460 (e.g., 460-1, 460-2, 460-3, 460-4, 460-5, 460-6, 460-7, and 460-8). Alternatively, several of the temperature sensors 440 may be added per unit refresh macro of the DRAM dies of the 3D DRAM stack 430. These temperature sensor placements enable implementation of different refresh period controls per bank 460 (or refresh control macro).

As shown in FIG. 5, eight refresh control banks (e.g., the banks 460 or macros) are counted on the DRAM dies of the 3D DRAM stack 430. This multiple temperature sensor driven refresh control can improve the defective parts per million (DPPM) degraded by the localized thermal regions of the SoC base die 420. In some implementations, the DRAM temperature sensor selection circuits 450 can select the required temperature sensor locations according to the number of localized thermal regions. This configuration enables fine-tunning of DRAM refresh according to the location of the localized thermal regions, which beneficially saves the standby power (IDD6) and auto refresh power (IDD5).

Various aspects of the present disclosure define a process for arranging a dynamic random-access memory (DRAM) temperature sensor location based on localized thermal regions (e.g., hotspots) of a system-on-chip (SoC) base die.

Additionally, the DRAM temperature sensors can be located according to portions of the SoC base die having a predetermined temperature range (e.g., between −40° C. to 25° C.) from a normal temperature range (e.g., 0° to 85° C. or 0° to 125° C.). As described, localized thermal regions of the SoC base die having a temperature exceeding the noted, normal temperature ranges may be referred to as hotspots or localized thermal regions. Multiple temperature sensors can be added at any location on the DRAM die, and each bank on the DRAM die can have a temperature sensor. A DRAM temperature sensor can also be located proximate to a statistically predicted localized thermal region of the SoC base die.

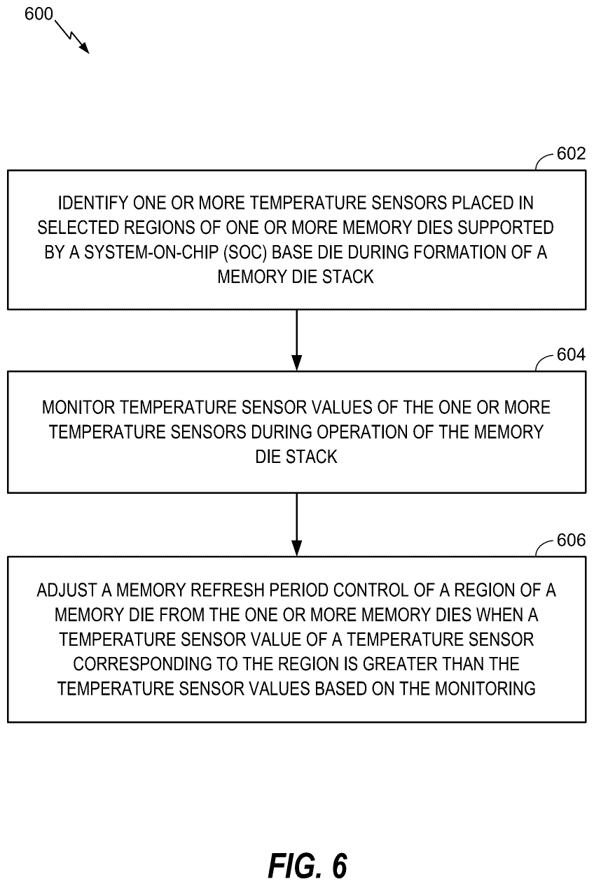

FIG. 6 is a process flow diagram illustrating a method for flexible memory refresh period control, according to various aspects of the present disclosure. At method 600 beings at block 602, in which one or more temperature sensors placed in selected regions of one or more memory dies supported by a system-on-chip (SoC) base die during formation of a memory die stack are identified. For example, as shown in FIG. 4, the temperature sensors 440 are added to a predetermined number of locations of the DRAM dies of the 3D DRAM stack 430 during formation of the 3D DRAM stack 430. For example, temperature sensors 440 may be added per bank 460. Alternatively, several of the temperature sensors 440 may be added per unit refresh macro of the DRAM dies of the 3D DRAM stack 430.

At block 604, temperature sensor values of the one or more temperature sensors are monitored during operation of the memory die stack. At block 606, a memory refresh period control of a region of a memory die from the one or more memory dies is adjusted when a temperature sensor value of a temperature sensor corresponding to the region is greater than the temperature sensor values based on the monitoring. For example, as shown in FIG. 4, the high-bandwidth 3D stacked memory package 400 is configured for a flexible, refresh period control method based on monitoring temperature sensor values of one or more memory dies, according to various aspects of the present disclosure.

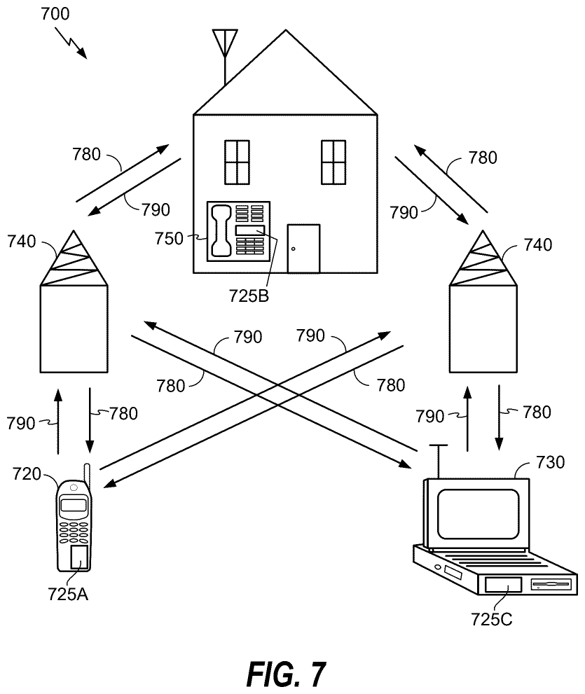

FIG. 7 is a block diagram showing an exemplary wireless communications system 700, in which an aspect of the present disclosure may be advantageously employed. For purposes of illustration, FIG. 7 shows three remote units 720, 730, and 750, and two base stations 740. It will be recognized that wireless communications systems may have many more remote units and base stations. Remote units 720, 730, and 750 include integrated circuit (IC) devices 725A, 725B, and 725C that include the disclosed 3D DRAM stack. It will be recognized that other devices may also include the disclosed 3D DRAM stack, such as the base stations, switching devices, and network equipment. FIG. 7 shows forward link signals 780 from the base stations 740 to the remote units 720, 730, and 750, and reverse link signals 790 from the remote units 720, 730, and 750 to the base stations 740.

In FIG. 7, remote unit 720 is shown as a mobile telephone, remote unit 730 is shown as a portable computer, and remote unit 750 is shown as a fixed location remote unit in a wireless local loop system. For example, the remote units may be a mobile phone, a hand-held personal communication systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof. Although FIG. 7 illustrates remote units according to the aspects of the present disclosure, the disclosure is not limited to these exemplary illustrated units. Aspects of the present disclosure may be suitably employed in many devices, which include the disclosed 3D DRAM stack.

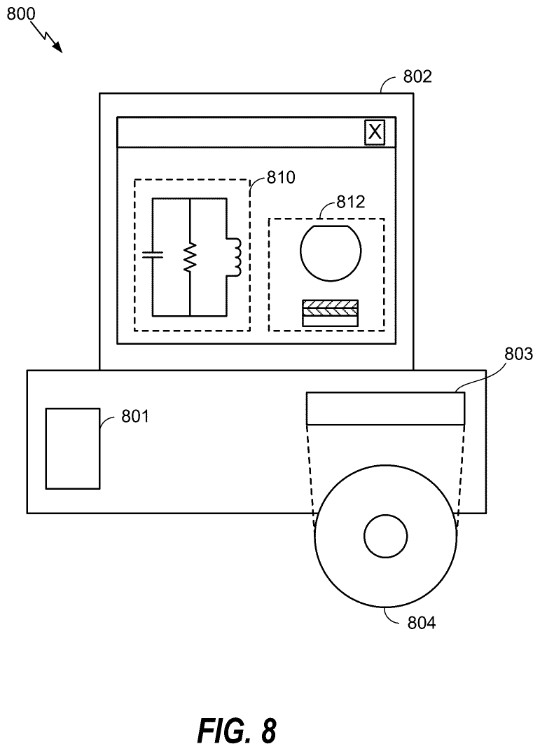

FIG. 8 is a block diagram illustrating a design workstation 800 used for circuit, layout, and logic design of a semiconductor component, such as the three-dimensional (3D) stacked chip disclosed above. The design workstation 800 includes a hard disk 801 containing operating system software, support files, and design software such as Cadence or OrCAD. The design workstation 800 also includes a display 802 to facilitate design of a circuit 810 or a semiconductor component 812, such as the 3D DRAM stack. A storage medium 804 is provided for tangibly storing the design of the circuit 810 or the semiconductor component 812 (e.g., the 3D DRAM stack). The design of the circuit 810 or the semiconductor component 812 may be stored on the storage medium 804 in a file format such as GDSII or GERBER. The storage medium 804 may be a CD-ROM, DVD, hard disk, flash memory, or other appropriate device. Furthermore, the design workstation 800 includes a drive apparatus 803 for accepting input from or writing output to the storage medium 804.

Data recorded on the storage medium 804 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 804 facilitates the design of the circuit 810 or the semiconductor component 812 by decreasing the number of processes for designing semiconductor wafers.

Implementation examples are described in the following numbered clauses:
1. A method for flexible memory refresh period control, the method comprising:
   identifying one or more temperature sensors placed in selected regions of one or more memory dies supported by a system-on-chip (SoC) base die during formation of a memory die stack;
   monitoring temperature sensor values of the one or more temperature sensors during operation of the memory die stack; and
   adjusting a memory refresh period control of a region of a memory die from the one or more memory dies when a temperature sensor value of a temperature sensor corresponding to the region is greater than the temperature sensor values based on the monitoring.
2. The method of clause 1, in which the identifying comprises programming a temperature sensor selection circuit to identify the one or more temperature sensors in the one or more memory die of the memory die stack.
3. The method of clause 1, further comprising:
   statistically estimating localized thermal regions of the SoC base die; and
   selecting the selected regions of the one or more memory die based on the statistically estimating of the localized thermal regions of the SoC base die.
4. The method of any of clauses 1-3, in which the identifying comprises selecting temperature sensors from a partial portion of the one or more memory die of the memory die stack.
5. The method of any of clauses 1-4, further comprising arranging the one or more temperature sensors according to banks of the one or more memory die as the selected regions.
6. The method of any of clauses 1-4, further comprising arranging the one or more temperature sensors per unit refresh macro of the one or more memory die as the selected regions.
7. The method of any of clauses 1-4, further comprising arranging the one or more temperature sensors according to localized thermal regions of the SoC base die.
8. The method of any of clauses 1-8, in which adjusting the memory refresh period control comprises selecting the refresh period control to ensure a predetermined memory cell retention of the one or more memory die.
9. The method of any of clauses 1-8, in which each of the one or more temperature sensors having a refresh control block to perform a memory refresh of the memory die corresponding to each of the one or more temperature sensors.
10. The method of any of clauses 1-9, in which the one or more memory dies comprise a plurality of dynamic random-access memory (DRAM) dies stacked on the SoC base die of a three-dimensional (3D) memory die stack.
11. An apparatus, comprising:
   a base system-on-chip (SoC) logic die; and
   a three-dimensional (3D) memory die stack on the base SoC logic die, comprising a plurality of memory dies, each of the plurality of memory dies having a plurality of temperature sensors and a temperature sensor selection circuit, in which locations of the plurality of temperature sensors correlate with locations of localized thermal regions of the base SoC logic die.
12. The apparatus of clause 11, in which the temperature sensor selection circuit is programmed to select one or more of the plurality of temperature sensors in the plurality of memory die of the 3D memory die stack.
13. The apparatus of clause 11, in which the temperature sensor selection circuit is configured to statistically select temperature sensors of the plurality of memory die of the 3D memory die stack.
14. The apparatus of clause 11, in which the temperature sensor selection circuit is configured to select temperature sensors from a partial portion of the plurality of memory die of the 3D memory die stack.
15. The apparatus of any of clauses 11-14, in which the plurality of temperature sensors are arranged according to banks of the plurality of memory die of the 3D memory die stack.
16. The apparatus of any of clauses 11-14, in which the plurality of temperature sensors are arranged per unit refresh macro of the plurality of memory die of the 3D memory die stack.
17. The apparatus of any of clauses 11-14, in which the plurality of temperature sensors are arranged according to statistically estimated localized thermal regions of the base SoC logic die.
18. The apparatus of any of clauses 11-17, in which a memory refresh period control of the 3D memory die stack is selected to ensure a predetermined memory cell retention of the plurality of memory die of the 3D memory die stack.
19. The apparatus of any of clauses 11-18, in which the plurality of memory die of the 3D memory die stack comprise a plurality of dynamic random-access memory (DRAM) dies.
20. The apparatus of any of clauses 11-19, in which each of the plurality of temperature sensors having a refresh control block to perform a memory refresh of a memory die corresponding to each of the plurality of temperature sensors.

For a firmware and/or software implementation, the methodologies may be implemented with modules (e.g., procedures, functions, and so on) that perform the functions described. A machine-readable medium tangibly embodying instructions may be used in implementing the methodologies described. For example, software codes may be stored in a memory and executed by a processor unit. Memory may be implemented within the processor unit or external to the processor unit. As used, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include random-access memory (RAM), read-only memory (ROM), electrically erasable read-only memory (EEPROM), compact disc read-only memory (CD-ROM) or other optical disk storage, magnetic disk storage or other magnetic storage devices, or other medium that can be used to store desired program code in the form of instructions or data structures and that can be accessed by a computer. Disk and disc, as used, include compact disc (CD), laser disc, optical disc, digital versatile disc (DVD), floppy disk, and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, various changes, substitutions, and alterations can be made without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present disclosure is not intended to be limited to the configurations of the process, machine, manufacture, composition of matter, means, methods, and steps described in the specification. As one of ordinary skill in the art will readily appreciate from the present disclosure, processes, machines, manufacture, compositions of matter, means, methods, or steps, presently existing or later to be developed that perform the same function or achieve the same result as the corresponding configurations described may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the present disclosure may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the application and design constraints imposed on the overall system. Skilled artisans may implement the described functionality in varying ways for each application, but such implementation decisions should not be interpreted as causing a departure from the scope of the present disclosure.

The various illustrative logical blocks, modules, and circuits described in connection with the disclosure may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in RAM, flash memory, ROM, erasable programmable read-only memory (EPROM), EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the present disclosure is provided to enable any person skilled in the art to make or use the present disclosure. Various modifications to the disclosure will be readily apparent to those skilled in the art, and the generic principles defined may be applied to other variations without departing from the spirit or scope of the disclosure. Thus, the present disclosure is not intended to be limited to the examples and designs described but is to be accorded the widest scope consistent with the principles and novel features disclosed.

What is claimed is:

1. A method for flexible memory refresh period control, the method comprising:
identifying one or more temperature sensors placed in selected regions of one or more memory dies supported by a system-on-chip (SoC) base die during formation of a memory die stack;
monitoring temperature sensor values of the one or more temperature sensors during operation of the memory die stack; and
adjusting a memory refresh period control of a region of a memory die from the one or more memory dies when a temperature sensor value of a temperature sensor corresponding to the region is greater than the temperature sensor values based on the monitoring.

2. The method of claim 1, in which the identifying comprises programming a temperature sensor selection circuit to identify the one or more temperature sensors in the one or more memory die of the memory die stack.

3. The method of claim 1, further comprising:
statistically estimating localized thermal regions of the SoC base die; and
selecting the selected regions of the one or more memory die based on the statistically estimating of the localized thermal regions of the SoC base die.

4. The method of claim 1, in which the identifying comprises selecting temperature sensors from a partial portion of the one or more memory die of the memory die stack.

5. The method of claim 1, further comprising arranging the one or more temperature sensors according to banks of the one or more memory die as the selected regions.

6. The method of claim 1, further comprising arranging the one or more temperature sensors per unit refresh macro of the one or more memory die as the selected regions.

7. The method of claim 1, further comprising arranging the one or more temperature sensors according to localized thermal regions of the SoC base die.

8. The method of claim 1, in which adjusting the memory refresh period control comprises selecting the refresh period control to ensure a predetermined memory cell retention of the one or more memory die.

9. The method of claim 1, in which each of the one or more temperature sensors having a refresh control block to perform a memory refresh of the memory die corresponding to each of the one or more temperature sensors.

10. The method of claim 1, in which the one or more memory dies comprise a plurality of dynamic random-access memory (DRAM) dies stacked on the SoC base die of a three-dimensional (3D) memory die stack.

11. An apparatus, comprising:
a base system-on-chip (SoC) logic die; and
a three-dimensional (3D) memory die stack on the base SoC logic die, comprising a plurality of memory dies, each of the plurality of memory dies having a plurality of temperature sensors and a temperature sensor selection circuit, in which locations of the plurality of temperature sensors correlate with locations of localized thermal regions of the base SoC logic die.

12. The apparatus of claim 11, in which the temperature sensor selection circuit is programmed to select one or more of the plurality of temperature sensors in the plurality of memory die of the 3D memory die stack.

13. The apparatus of claim 11, in which the temperature sensor selection circuit is configured to statistically select temperature sensors of the plurality of memory die of the 3D memory die stack.

14. The apparatus of claim 11, in which the temperature sensor selection circuit is configured to select temperature sensors from a partial portion of the plurality of memory die of the 3D memory die stack.

15. The apparatus of claim 11, in which the plurality of temperature sensors are arranged according to banks of the plurality of memory die of the 3D memory die stack.

16. The apparatus of claim 11, in which the plurality of temperature sensors are arranged per unit refresh macro of the plurality of memory die of the 3D memory die stack.

17. The apparatus of claim 11, in which the plurality of temperature sensors are arranged according to statistically estimated localized thermal regions of the base SoC logic die.

18. The apparatus of claim 11, in which a memory refresh period control of the 3D memory die stack is selected to ensure a predetermined memory cell retention of the plurality of memory die of the 3D memory die stack.

19. The apparatus of claim 11, in which the plurality of memory die of the 3D memory die stack comprise a plurality of dynamic random-access memory (DRAM) dies.

20. The apparatus of claim 11, in which each of the plurality of temperature sensors having a refresh control block to perform a memory refresh of a memory die corresponding to each of the plurality of temperature sensors.
